(19) United States
(12) Patent Application Publication
(10) Pub. No.: US 2010/0078813 A1
(43) Pub. Date: Apr. 1, 2010

(54) SEMICONDUCTOR MODULE AND METHOD FOR MANUFACTURING THE SEMICONDUCTOR MODULE

(76) Inventors: Yoshio OKAYAMA, Osaka (JP); Mayumi Nakasato, Osaka (JP)

Correspondence Address: MCDERMOTT WILL & EMERY LLP, 600 13TH STREET, N.W., WASHINGTON, DC, 20005-3096, US

(21) Appl. No.: 12/570,549

(22) Filed: Sep. 30, 2009

(30) Foreign Application Priority Data
Sep. 30, 2008 (JP) 2008-254412

(51) Int. Cl. H01L 23/488; H01L 21/60

(52) U.S. Cl. 257/738; 438/121; 257/E21.509; 257/E23.023

(57) ABSTRACT

A semiconductor module includes a device mounting board and a semiconductor device mounted on the device mounting board. The device mounting board includes an insulating resin layer, a wiring layer provided on one main surface of the insulating layer, and a bump electrode which is electrically connected to the wiring layer and protruded from the wiring layer in an insulating layer side. The semiconductor device has device electrodes disposed counter to the semiconductor substrate and the bump electrodes, respectively. The surface of a metallic layer provided on the device electrode has a rugged shape, resulting in the improved adhesion between the metallic layer and the insulating resin layer.

### CROSS-REFERENCE TO RELATED APPLICATIONS

This application is based upon and claims the benefit of priority from the prior Japanese Patent Applications No. 2008-255412, filed on Sep. 30, 2008, the entire contents of which are incorporated herein by reference.

### BACKGROUND OF THE INVENTION

1. Field of the Invention

The present invention relates to a semiconductor module mounting a semiconductor device thereon, a manufacturing method therefor, and a mobile apparatus carrying the semiconductor module.

2. Description of the Related Art

In recent years, with miniaturization and higher performance in electronic devices, demand has been ever greater for further miniaturization of semiconductor devices used in the electronic devices. With such miniaturization of semiconductor devices, it is of absolute necessity that the pitch of electrodes to enable mounting on a wiring board be made narrower. A known method of surface-mounting a semiconductor device is flip-chip mounting in which solder balls are formed on electrodes of the semiconductor device and the solder balls are soldered to an electrode pad of the wiring board. With this flip-chip method, however, there are restrictive factors for the narrowing of the pitch of electrodes, such as the size of the solder ball itself and the bridge formation at soldering. As one structure used to overcome these limitations, known is a structure where a bump structure formed by half-etching a substrate is used as an electrode or a via, and the electrodes of the semiconductor device are connected to the bump structure by mounting the semiconductor device on the substrate with an insulating resin layer, such as epoxy resin, held between the semiconductor device and the substrate.

On the other hand, a semiconductor device is disclosed where an electrode exposed in an opening formed in an insulating layer is provided. In this semiconductor device, a side wall of the insulating layer is located around the electrode.

In order to resolve the problem of faults or degradation in adhesion between a wiring layer made of metal and an insulating resin, there is known a technique where a conductive resin layer into which metallic powders are mixed is used as the wiring layer. In this technique, there is still a problem where the adhesion between device electrodes formed on a semiconductor substrate and the insulating resin layer is low.

### SUMMARY OF THE INVENTION

The present invention has been made in view of the foregoing circumstances, and a purpose thereof is to provide a technology for improving the connection reliability between electrodes and bump electrodes provided in a semiconductor device.

One embodiment of the present invention relates to a semiconductor module. This semiconductor module comprises: a semiconductor device formed on a semiconductor substrate; and a device mounting board which mounts the semiconductor device thereon via an insulating layer, wherein the device electrode in the semiconductor device is formed by a plurality of metallic layers; among the plurality of metallic layers, the depth of surface roughness of a metallic layer disposed farthest from the semiconductor substrate is larger than that of the other metallic layers thereamong; and the insulating layer is in contact with a rugged shape of the device electrode.

In the above semiconductor module, the device mounting board includes: the insulating layer; a wiring layer provided on one main surface of the insulating layer; and a bump electrode which is electrically connected to the wiring layer and protruded from the wiring layer in an opposite side of the insulating layer, wherein the bump electrode and the device electrode of the semiconductor device are electrically connected to each other, and the insulating layer is in contact with the rugged shape of the device electrode.

By employing this embodiment, the insulating layer enters the rugged shape formed on the surface of the device electrode. This helps prevent the insulating layer and the device electrode from being separated from each other and at the same time can improve the electrical connection between the device electrode and the bump electrode.

In the semiconductor module according to the above embodiment, the device electrode may include a Ni/Au layer.

In the semiconductor module according to this embodiment, the wiring layer and the bump electrode may be formed integrally with each other. Also, a Ni/Au layer may be provided on a top surface of the bump electrode.

Another embodiment of the present invention relates to a portable device. This portable device mounts any of the above-described semiconductor modules.

Still another embodiment of the present invention relates to a method for manufacturing a semiconductor module. The method for manufacturing a semiconductor module comprises: preparing a semiconductor device wherein a device electrode formed on a semiconductor substrate is formed by a plurality of metallic layers and, among the plurality of metallic layers, the depth of roughness of surface of a metallic layer disposed farthest from the semiconductor substrate is larger than that of the other metallic layers thereamong; preparing a metallic sheet where a plurality of bump electrodes are provided in a protruding manner; placing the metallic sheet on one main surface of an insulating resin layer in such a manner that the bump electrodes face the insulating resin layer, and exposing the bump electrodes from the other main surface of the insulating resin layer by having the bump electrodes penetrating the insulating resin layer; placing the semiconductor device, provided with the device electrodes, on the other main surface of the insulating resin layer, and electrically connecting the bump electrodes to the device electrodes corresponding thereto; and forming a wiring layer by selectively removing the metallic sheet.

Still another embodiment of the present invention relates to a method for manufacturing a semiconductor module. The method for manufacturing a semiconductor module comprises: preparing a semiconductor device wherein a device electrode formed on a semiconductor substrate is formed by a plurality of metallic layers and, among the plurality of metallic layers, the depth of roughness of surface of a metallic layer disposed farthest from the semiconductor substrate is larger than that of the other metallic layers thereamong; preparing a device mounting board having an electrode formed on one main face thereof; electrically connecting the device electrode to the electrode; and forming an insulating resin layer in between the semiconductor device and the device mounting board.

It is to be noted that any arbitrary combinations or rearrangement, as appropriate, of the aforementioned constituting elements and so forth are all effective as and encompassed by the embodiments of the present invention.

### BRIEF DESCRIPTION OF THE DRAWINGS

Embodiments will now be described by way of examples only, with reference to the accompanying drawings which are meant to be exemplary, not limiting and wherein like elements are numbered alike in several Figures in which:

FIG. 1 is a schematic cross-sectional view showing a structure of a semiconductor device and a semiconductor module according to a first embodiment of the present invention;

FIGS. 2A to 2C are cross-sectional views showing a process in a method for forming a semiconductor device;

FIGS. 3A to 3D are cross-sectional views showing a process in a method for forming bump electrodes;

FIGS. 4A to 4D are cross-sectional views showing a process in a method for forming metallic layers on the top surfaces of bump electrodes;

FIGS. 5A and 5B are cross-sectional views showing a process in a method for exposing heads of bump electrodes;

FIGS. 6A to 6C are cross-sectional views showing a process in a method for pasting together a semiconductor device and a device mounting board on which a semiconductor device and bump electrodes are provided;

FIGS. 7A and 7B are cross-sectional views each showing a rewiring process;

FIG. 8 is a schematic cross-sectional view showing a structure of a semiconductor module according to a second embodiment of the present invention;

FIGS. 9A to 9E are cross-sectional views showing a process in a method for forming a semiconductor module according to a second embodiment of the present invention;

FIG. 10 illustrates a structure of a mobile phone according to a third embodiment of the present invention;

FIG. 11 is a partial cross-sectional view of a mobile phone.

FIGS. 12A and 12B are AFM images each showing a condition of surface of a metallic layer;

FIGS. 13A and 13B are AFM images each showing a condition of surface of a metallic layer;

FIGS. 14A and 14B are cross-sectional views each showing a condition of surface containing a metallic layer;

FIG. 15 is a cross-sectional view showing a method for evaluating adhesion strength; and

FIG. 16 is a graph showing a relation between the surface roughness and the adhesion strength.

### DETAILED DESCRIPTION OF THE INVENTION

The invention will now be described by reference to the preferred embodiments. This does not intend to limit the scope of the present invention, but to exemplify the invention.

Hereinbelow, the embodiments will be described with reference to the accompanying drawings. Note that in all of the Figures the same reference numerals are given to the same components and the description thereof is omitted as appropriate. Moreover, the embodiments given are for illustrative purposes only and all features and their combination thereof described in the present embodiment are not necessarily essential to the invention.

### First Embodiment

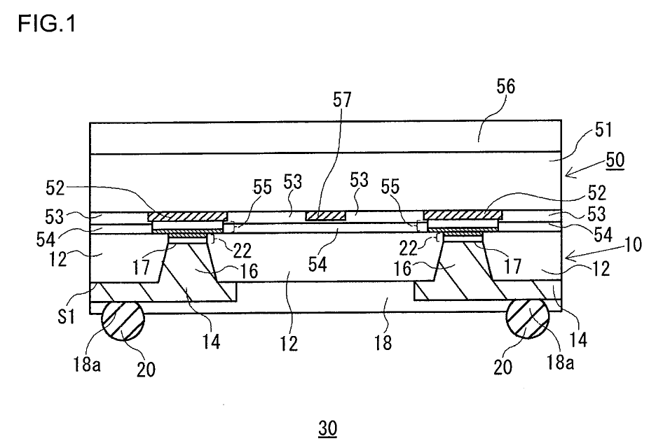

FIG. 1 is a schematic cross-sectional view showing a structure of a semiconductor device 50 and a semiconductor module 30 according to a first embodiment of the present invention. The semiconductor module 30 includes a device mounting board 10 and a semiconductor device 50 mounted on the device mounting board 10.

The device mounting board 10 includes an insulating resin layer 12, a wiring layer 14 provided on one main surface S1 of an insulating resin layer 12, and a bump electrode 16, electrically connected to the wiring layer 14, which is protruded (projected) from the wiring layer 14 toward an insulating resin layer 12 side.

The insulating resin layer 12 is made of insulating resin and is formed of, for example, a material that develops plastic flow when pressurized. An example of the material that develops plastic flow when pressurized is epoxy thermosetting resin. The epoxy thermosetting resin to be used for the insulating resin layer 12 may be, for example, one having viscosity of 1 kPa·s under the conditions of a temperature of 160° C. and a pressure of 8 MPa. If a pressure of 5 to 15 MPa is applied to this epoxy thermosetting resin at a temperature of 160° C., then the viscosity of the resin will drop to about ⅛ of the viscosity thereof with no pressurization. In contrast to this, an epoxy resin in B stage before thermosetting has no viscosity, similarly to a case when the resin is not pressurized, under a condition that the temperature is less than or equal to a glass transition temperature Tg. And the epoxy resin develops no viscosity even when pressurized under a condition that the temperature is less than or equal to the glass transition temperature Tg. Also, this epoxy thermosetting resin is a dielectric substance having a permittivity of about 3 to 4.

The wiring layer 14 is provided on one main surface S1 of the insulating resin layer 12 and is formed of a conducive material, preferably of a rolled metal or more preferably of a rolled copper. Or the wiring layer 14 may be formed of electrolyte copper or the like. The bump electrode 16 is provided, in a protruding manner, on the insulating resin layer 12 side. In the first embodiment, the wiring layer 14 and the bump electrode 16 are formed integrally with each other and thereby the connection between the wiring layer 14 and the bump electrode 16 is assured. Moreover, the electrical connection between the bump electrode 16 and a device electrode 52 can be secured simultaneously when the wiring layer 14 is press-bonded, without adding the connection process by bonding wire or solders. Hence, an advantageous effect of not increasing the number of processes can be achieved. Note that the preferred embodiments are not particularly limited to the structure where the wiring layer 14 and the bump electrode 16 are formed integrally with each other. A protective layer 18 is provided on a main surface of the wiring layer 14 opposite to the insulating resin layer 12. This protective layer 18 protects the wiring layer 14 against oxidation or the like. The protective layer 18 may be a photo solder resist layer, for instance. An opening 18a is formed in a predetermined position of the protective layer 18, and the wiring layer 14 is partially exposed there. A solder ball 20, which functions as an external connection electrode, is formed within the opening 18a. And the solder ball 20 and the wiring layer 14 are electrically connected to each other. The position in which the solder ball 20 is formed, namely, the area in which the opening 18a is formed is, for instance, an end where circuit wiring is extended through a rewiring.

The overall shape of the bump electrode 16 is narrower toward the tip portion thereof. In other words, the side surface of the bump electrode 16 is tapered. A metallic layer 22 is provided on a top surface 17 of the bump electrode 16. A Ni/Au plating layer is preferable as the metallic layer 22.

The semiconductor device 50 is mounted on the device mounting board 10 having the above-described structure so as to form the semiconductor module 30. The semiconductor module 30 according to the first embodiment is structured such that a bump electrode 16 of the device mounting board 10 is electrically connected to a device electrode 52 of the semiconductor device 50 through the medium of the metallic layer 22 and the metallic layer 55.

The semiconductor device 50 has device electrodes 52 disposed counter to the semiconductor substrate 51 and the bump electrodes 16, respectively. An insulating layer 53 and a protective layer 54, in which openings are provided so that the device electrodes 52 can be exposed from the openings, are stacked on the main surface of the semiconductor device 50. The metallic layer 55 covers a surface of the device electrode 52. An alignment mark 57 is provided in a predetermined position of the semiconductor substrate 51. The alignment mark 57 may be covered by the insulating layer 53 as in this first embodiment as long as the alignment mark 57 is optically visible. In a modification of the first embodiment, the alignment mark 57 may be provided in the opening of the insulating layer 53 and the protective layer 54. Also, an insulating layer 56 is provided on the back side of the semiconductor substrate 51. It is to be note that the device electrode 52 and metallic layer 55 together may be simply called “device electrode” also.

In the first embodiment, the surface of the metallic layer 55 (device electrode) is a rugged shape, and the insulating resin layer 12 is partially in contact with this rugged shape.

A specific example of the semiconductor device 50 is a semiconductor chip such as an integrated circuit (IC) or a large-scale integrated circuit (LSI). A specific example of the insulating layer 53 is a silicon nitride film (SiN film). A specific example of the protective layer 54 is a polyimide layer. For example, aluminum (Al) is used as the device electrode 52. A Ni/Au plating layer is preferable as the metallic layer 55. A specific example of the insulating layer 56 is an epoxy resin film.

A description is now given of the rugged shape formed on the surface of a device electrode.

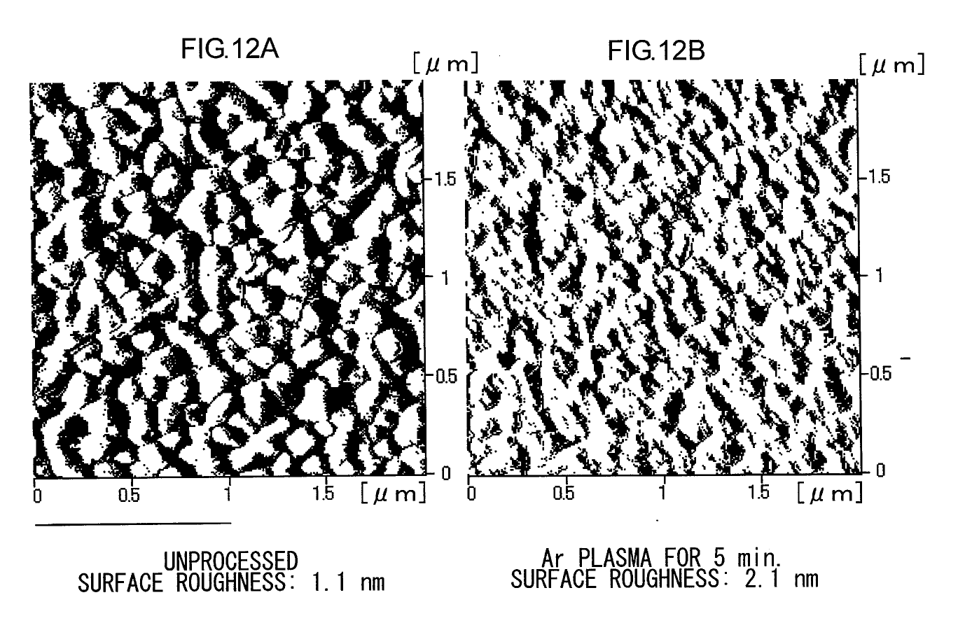

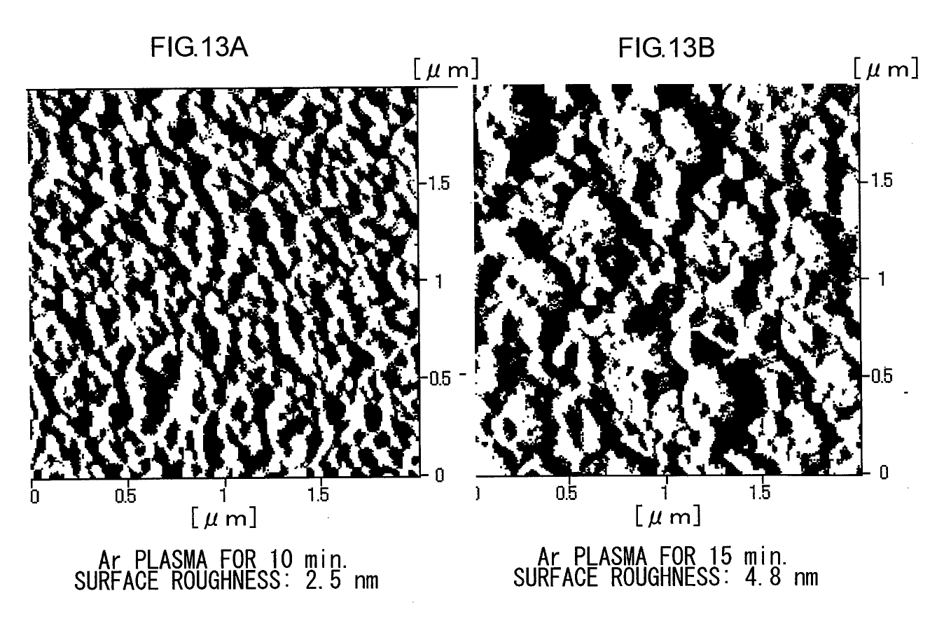

Referring to FIGS. 12A and 12B and FIGS. 13A and 13B, in the order closer to the device electrode, the conditions of surface (e.g., surface roughness) of a device electrode on which a metallic layer 55 formed of nickel (Ni) and gold (Au) is stacked.

FIG. 12A is an AFM (Atomic Force Microscope) image showing the condition of surface of a metallic layer 55 which is not subjected to plasma processing. FIG. 12B, FIG. 13A and FIG. 13B are AFM images each showing the condition of surface of a metallic layer 55 which is subjected to argon (Ar) plasma processing.

The condition for each plasma processing is set as follows. For the case of FIG. 12B, the plasma processing time is 5 minutes and the surface roughness is 2.1 nm; for the case of FIG. 13A, the plasma processing time is 10 minutes and the surface roughness is 2.5 nm; and for the case of FIG. 13B, the plasma processing time is 15 minutes and the surface roughness is 4.8 nm. Note that the surface roughness meant here is an average roughness in the center line of arbitrary cross section.

Compared with the condition of surface of the metallic layer 55 (shown in FIG. 12A) which is not subjected to plasma processing, the surface of the metallic layer 55 which has been subjected to plasma processing has a higher surface roughness.

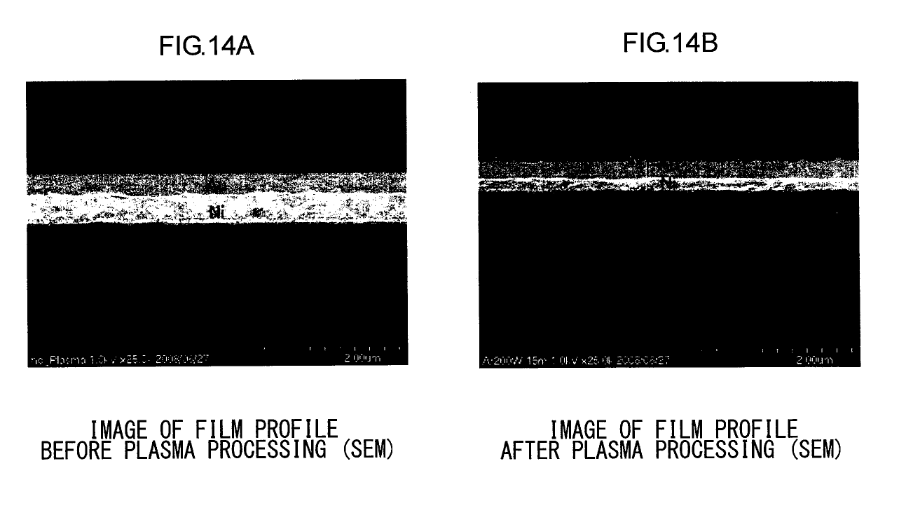

FIG. 14A is a photograph showing a cross section of a semiconductor module containing a metallic layer 55 which is not subjected to plasma processing. FIG. 14B is a photograph showing a cross section thereof containing a metallic layer 55 which has been subjected to plasma processing.

As shown in FIGS. 12A and 12B, it is found that the surface of Au which has been subjected to plasma processing has a larger asperity than the surface of Au which is not subjected to plasma processing. Also, it is seen from FIGS. 12A and 12B that, as compared with the surface roughness of the outermost Au film, the surface roughness of a Ni film which is a lower layer disposed below the Au film is smaller. The bump electrode 16 and the insulating layer 12 are electrodes that adhere tightly to the metallic layer 55. Since the surface roughness of the outermost surface of the metallic layer 55 is large, the electric connection between the metallic layer 55 and the bump electrode 16 is improves. Also, since an insulating resin enters the rugged surface, the adhesion between the metallic layer 55 and the insulating resin can be improved.

A description is now given of evaluation of adhesion strength using the asperities of surface of the metallic layer.

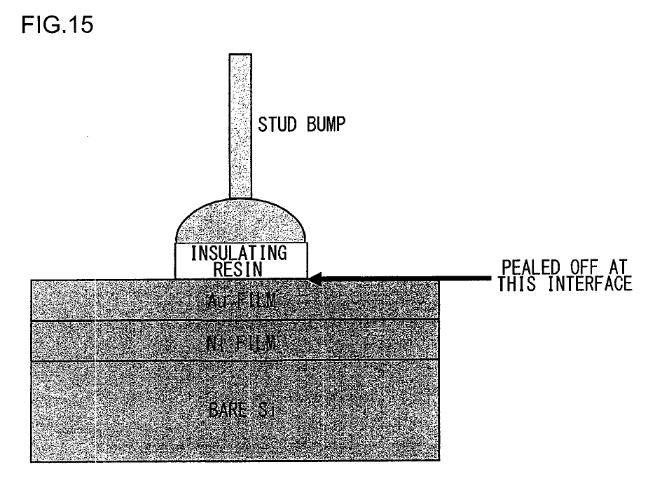

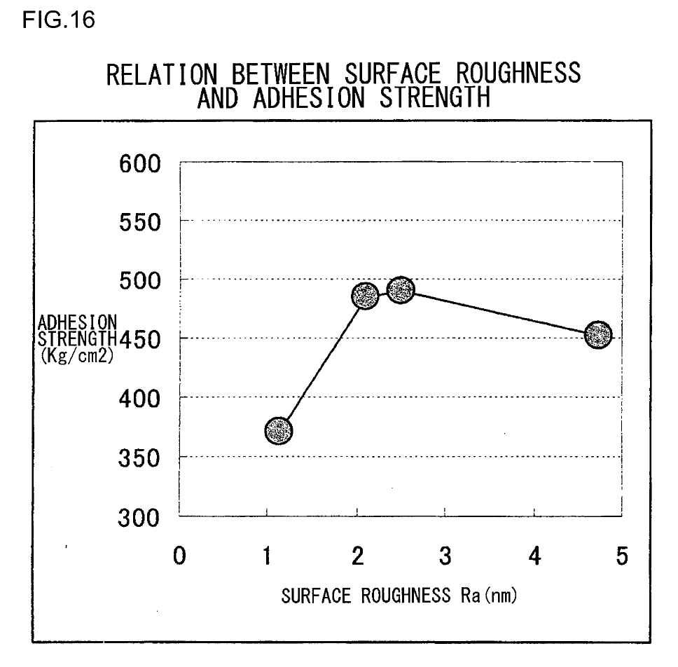

FIG. 15 illustrates a method for evaluating adhesion strength. FIG. 16 is a graph showing a relation between the surface roughness Ra and the adhesion strength.

The adhesion strength is evaluated as flows. That is, a Ni film, an Au film, and an insulating resin are stacked in this order so as to form a stud bump on the surface of the insulating resin. Then the stud bump is pulled up and the force acting when the insulating resin and Au film are peeled off is converted to the force per unit area, which in turn measures the adhesion strength.

FIG. 16 shows this result indicating a relation between the surface roughness (horizontal axis) and the adhesion strength (vertical axis). It can be found from FIG. 16 that the adhesion strength is strongest when the surface roughness is in a range of 2 nm to 2.5 nm.

(Method for Manufacturing a Semiconductor Device and a Semiconductor Module)

A method for manufacturing a semiconductor device and a semiconductor module according to the first embodiment is now described.

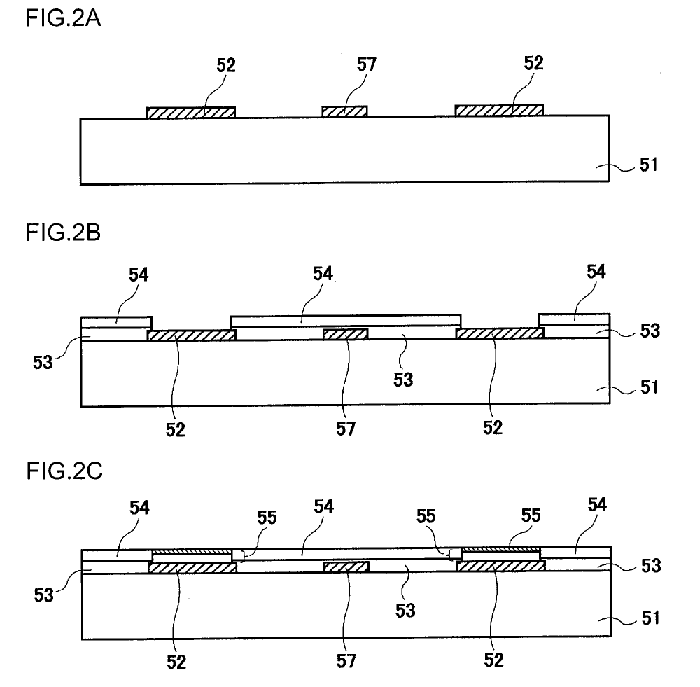

FIGS. 2A to 2C are cross-sectional views showing a process in a method for forming the semiconductor device.

As illustrated in FIG. 2A, a semiconductor substrate 51 on which a device electrode 52 constituting a part of a device electrode is prepared. The semiconductor substrate 51 is an Si substrate, for example, on which an integrated circuit (IC) or a large-scale integrated circuit (LSI) is formed. The device electrode 52 can be formed by patterning Al, for instance. An alignment mark 57 is provided in a predetermined position of the semiconductor substrate 51. The alignment mark 57 can be formed simultaneously when Al for use as the device electrode 52 is patterned, for instance. That is, the alignment mark 57 in such a case is formed of Al. However, it suffices if the alignment mark 57 is optically visible, and the alignment mark 57 may be formed using other materials or processes.

Then, as shown in FIG. 2B, an insulating layer 53 and a protective layer 54 are so formed as to cover the surface of the semiconductor substrate 51 around the device electrode 52, using a photoresist technique. For example, silicon nitride (SiN) may be used as the insulating layer 53. For example, polyimide may be used as the protective layer 54

Then, as shown in FIG. 2C, a metallic layer 55 comprised of a Ni/Au plating layer is formed on the device electrode 52 by electroless plating.

Here, plasma processing is performed on the surface of the metallic layer 55 so that the surface of the metallic layer 55 is a rugged shape. More precisely, for example, the plasma using Ar (argon) gas is applied for 10 minutes. As a result, the rugged shape of about 2.5 nm is formed on the surface of the device electrode 52, namely the metallic layer 55. Thus, the semiconductor device 50 is manufactured through processes as described above.

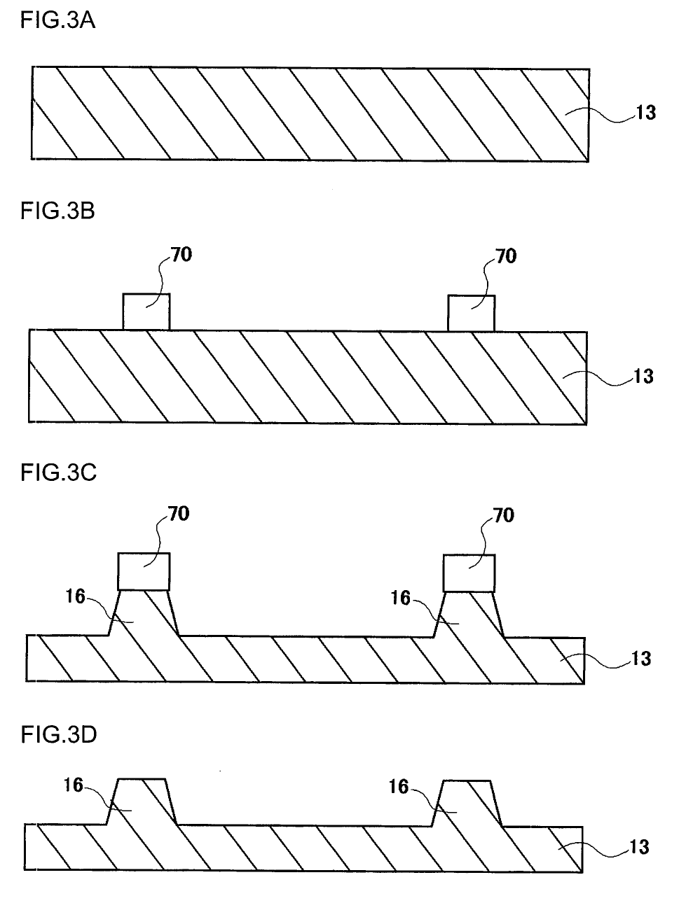

FIGS. 3A to 3D are cross-sectional views showing a process in a method for forming bump electrodes.

As illustrated in FIG. 3A, a copper sheet 13 is prepared as a metallic sheet having a thickness greater than at least the sum of the height of the bump electrode 16 and the thickness of the wiring layer 14 as shown in FIG. 1. The thickness of the copper sheet is 125 μm, for instance.

Then, as shown in FIG. 3B, resists 70 are formed selectively in alignment with a pattern that corresponds to a predetermined formation region of bump electrodes 16 using a lithography method. More specifically, a resist film of predetermined film thickness is affixed to the copper sheet 13 by a laminating apparatus, and it is then subjected to exposure using a photo mask having the pattern of bump electrodes 16. After this, the resists 70 are selectively formed on the copper sheet 13 by a development. To improve the adhesion of the resists 70 to the copper sheet 13, it is desirable that a pretreatment, such as grinding and cleaning, be performed as necessary on the surface of the copper sheet 13 before the lamination of the resist film thereon.

Then, as shown in FIG. 3C, bump electrodes 16 having a predetermined pattern are formed on the copper sheet 13 using the resists 70 as a mask.

Then, as shown in FIG. 3D, the resists 70 are removed using a stripping agent. Thus the bump electrodes 16 are formed on the copper sheet 13 through a process as described above. The diameter of the base, the diameter of the top, and the height of the bump electrode 16 according to the first embodiment are 100 to 140 μmφ, 50 μmφ and 20 to 25 μmφ, respectively, for instance.

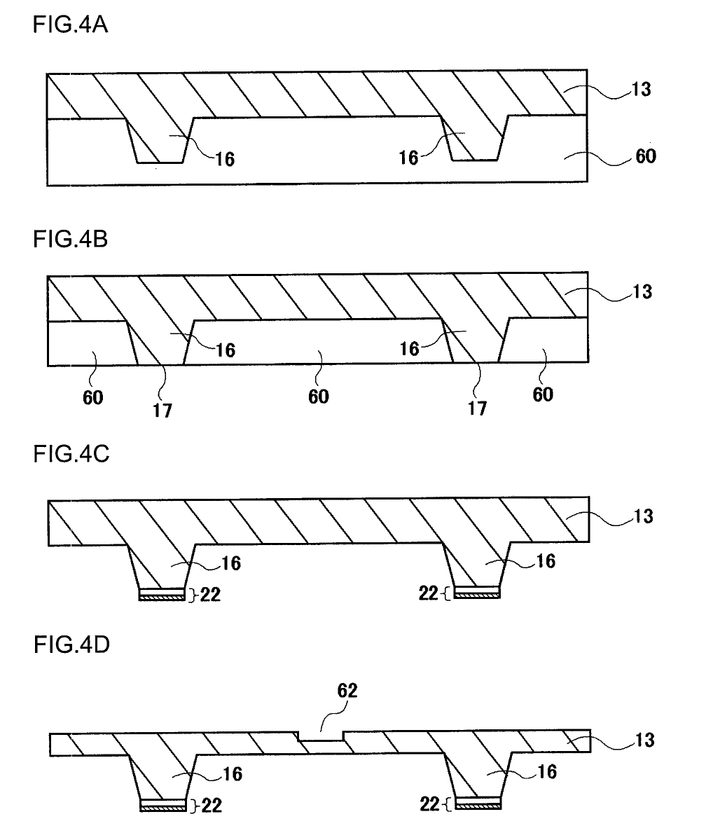

FIGS. 4A to 4D are cross-sectional views showing a process in a method for forming metallic layers on the top surfaces of bump electrodes.

As shown in FIG. 4A, a gold-resistant resist 60 are stacked on the copper sheet 13 in a side where the bump electrodes are formed, using a laminating apparatus.

Then, as shown in FIG. 4B, the gold-resistant resist 60 is turned into thin film by the use of O₂ plasma etching so that the top surface 17 of the bump electrode 16 is exposed.

Then, as shown in FIG. 4C, a metallic layer 22 comprised of a Ni/Au layer is formed on the top surface of the bump electrode 16 by electroless plating. After the formation of this metallic layer 22, the gold-resistant resist 60 is removed.

Then, as shown in FIG. 4D, the surface of the copper sheet 13 in a side opposite to the side where the bump electrodes 16 are provided is etched back and thereby the copper sheet 13 is turned into thin film. Then, a recess 62 serving as the alignment mark is formed by etching a predetermined region of the copper sheet 13 using a not-shown resist.

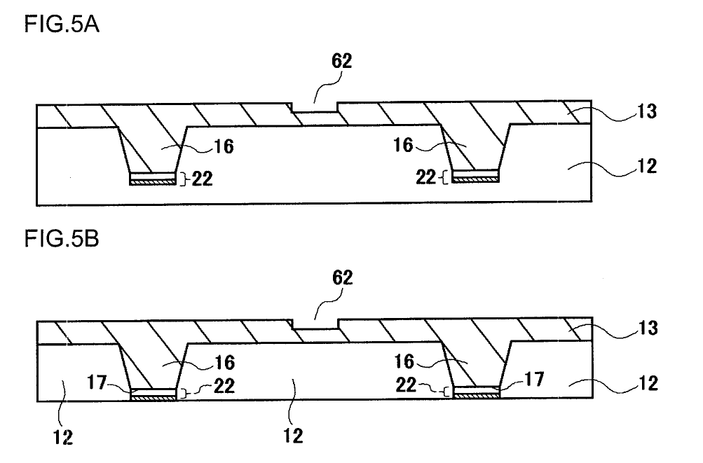

FIGS. 5A and 5B are cross-sectional views showing a process in a method for exposing heads of bump electrodes.

As shown in FIG. 5A, an insulating resin layer 12 is stacked on the surface of the copper sheet 13 on the side where the bump electrodes 16 are provided, using a vacuum laminating method. For example, an epoxy thermosetting resin can be used as the insulating resin layer 12.

Then, as shown in FIG. 5B, the insulating resin layer 12 is turned into thin film by the use of O₂ plasma etching so that the metallic layer 22 provided on the top surface 17 of the bump electrode 16 is exposed. In this first embodiment, Au is exposed as the surface of the metallic layer 22.

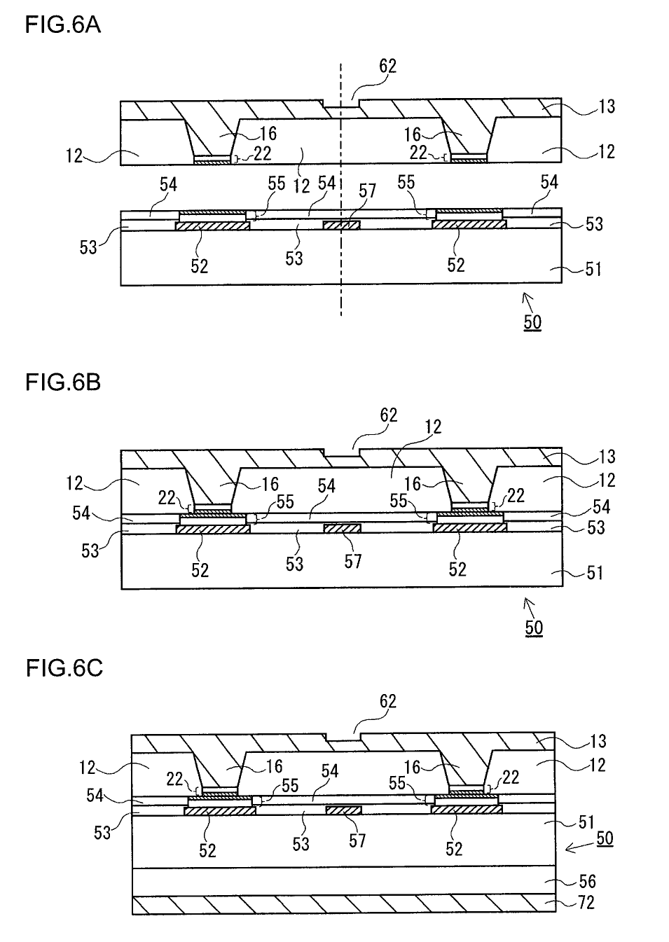

FIGS. 6A to 6C are cross-sectional views showing a process in a method for pasting together a semiconductor device and a device mounting board on which a semiconductor device and bump electrodes are provided.

As shown in FIG. 6A, the positions of the recess 62 provided in the copper sheet 13 and the alignment mark 57 provided on the semiconductor substrate 51 are adjusted by using an alignment apparatus or the like.

Then, as shown in FIG. 6B, the insulating resin layer 12 and the semiconductor device 50 are temporarily bonded in a central part of the copper sheet 13 which is a region where the recess 62 is provided.

Then, as shown in FIG. 6C, an insulating layer 56 with a copper foil 72 is pasted on the back side of the semiconductor device 50 and, at the same time, the insulating resin layer 12, the metallic layer 22 and the semiconductor device 50 are pasted together by vacuum press bonding. In the first embodiment, Au—Au bonding occurs between the metallic layer 22 provided on the bump electrode 16 in the device mounting board 10 side and the metallic layer 55 provided on the device electrode 52 in the semiconductor device 50 side.

The provision of a rugged shape on the surface of the metallic layer 55 causes the insulating resin layer 12 to enter the asperities thereof in a region being in contact with the insulating resin layer 12, thereby improving the adhesion between the metallic layer 55 and the insulating resin layer 12. At the same time the connection between the metallic layer 22 and the insulating resin layer 12 can be assured in a region which is electrically connected to the metallic layer 22.

Also, the insulating layer 56 having the copper foil 72 is bonded to the back side of the semiconductor device 50. As a result, the warping of the copper sheet 13 is canceled out by the warping of the copper foil 72, thereby preventing the occurrence of the warping as a whole. It is desirable that the thickness of the copper foil 72 is the same as that of the copper sheet 13.

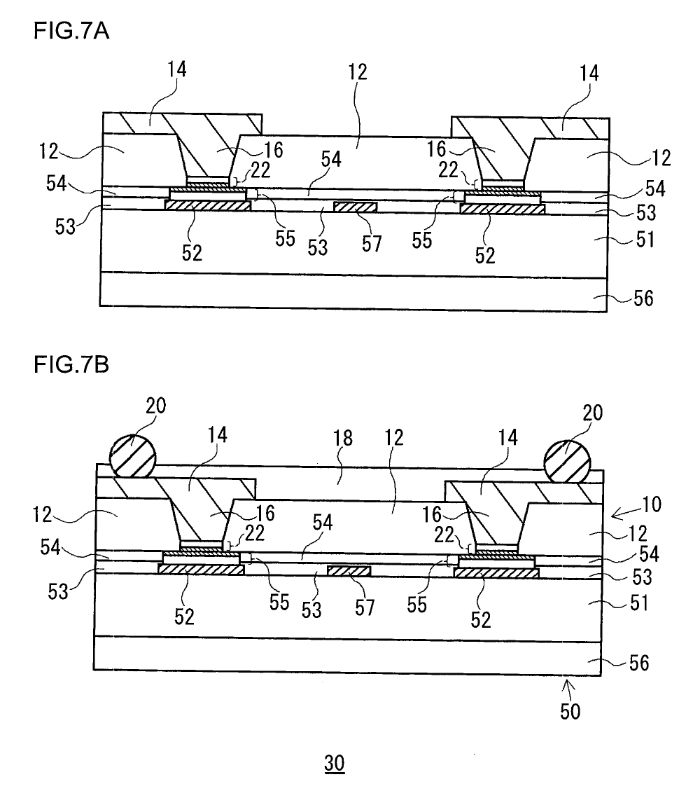

FIGS. 7A and 7B are cross-sectional views showing a rewiring process.

As shown in FIG. 7A, the copper sheet 13 is selectively removed by using a photolithography method and an etching method so as to form a wiring layer 14 (hereinafter referred to as “rewiring layer” also).

Then, as shown in FIG. 7B, a protective layer (photo solder resist layer) 18 is stacked on the wiring layer 14 and the insulating resin layer 12. Then, openings are provided in predetermined regions (mounting regions of solder balls) of the protective layer 18 by using the photolithography method, and the solder balls 20 are mounted in these openings by using a screen printing method.

Thus, the semiconductor module 30 is manufactured through processes as described above. If the above-described processes are to be done at a wafer level, a semiconductor wafer is diced into individual modules.

Since the connection reliability between the device electrode 52 and the bump electrode 16 in the semiconductor device 50 side is enhanced, the reliability of the semiconductor module 30 is improved. Also, the manufacturing yield of the semiconductor modules 30 can be improved and therefore the manufacturing cost of the semiconductor module 30 can be reduced.

### Second Embodiment

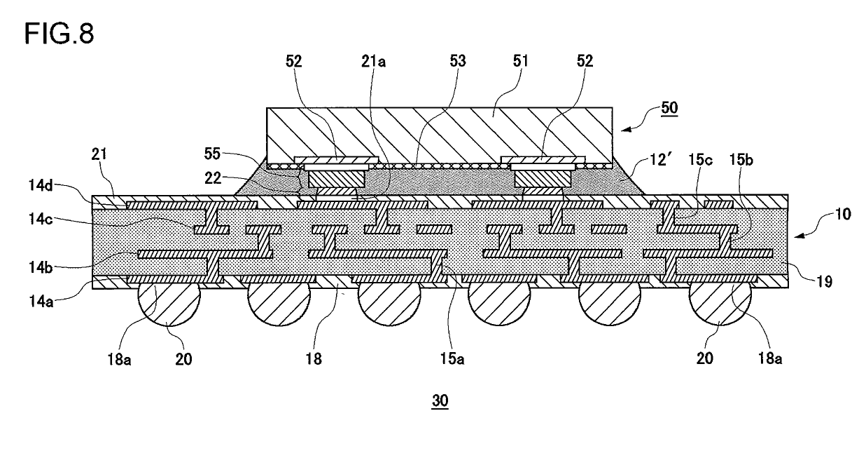

FIG. 8 is a cross-sectional view showing a structure of a semiconductor device 50 and a semiconductor module 30 according to a second embodiment of the present invention. The semiconductor module 30 includes a device mounting board 10 and a semiconductor device 50 mounted on the device mounting board 10. In the second embodiment, the semiconductor device 50 is flip-chip connected to the device mounting board 10.

The device mounting board 10 is a multilayered wiring board or printed circuit board formed by a known process such as a buildup process. More specifically, the device mounting board 10 comprises a multilayered wiring including wiring layers 14a, 14b, 14c and 14d, an interlayer insulation films 19 interposed between the wiring layers, via conductors 15a, 15b and 15c, and protective layers 18 and 21.

The wiring layer 14a is provided on one main surface of the interlayer insulation film 19 on a side where a solder ball 20 is mounted. And the wiring layer 14a and the interlayer insulation film 19 are covered with the protective layer 18, such as a solder resist layer, on the solder-ball-20-mounted side. An opening 18a is formed in a predetermined position of the protective layer 18, and the wiring layer 14a is partially exposed there. A solder ball 20, which functions as an external connection electrode, is formed within the opening 18a. And the solder ball 20 and the wiring layer 14a are electrically connected to each other. The position in which the solder ball 20 is formed, namely, the area in which the opening 18a is formed is, for instance, an end where circuit wiring is extended through a rewiring.

The wiring layers 14b and 14c are wiring layers formed between the wiring layer 14a and the wiring layer 14d, and each of the wiring layers 14b and 14c has a predetermined pattern used for the extended wiring.

The wiring layer 14d is provided on one main surface of the interlayer insulation film 19 on a side where the semiconductor device 50 is mounted. And the wiring layer 14d and the interlayer insulation film 19 are covered with the protective layer 21, such as a solder resist layer, on the semiconductor-device-50-mounted side. An opening 21a is formed in a predetermined position of the protective layer 18, and the wiring layer 14d is partially exposed there. A metallic layer 22 is provided within the opening 21a as an electrode. A Ni/Au plating layer is preferable as the metallic layer 22.

The semiconductor device 50 is mounted on the device mounting board 10 having the above-described structure so as to form the semiconductor module 30. The semiconductor module 30 according to the second embodiment is structured such that the metallic layer 22 provided on the device mounting board 10 is electrically connected to a metallic layer 55 provided on a device electrode 52 of the semiconductor device 50.

In the semiconductor device according to the second embodiment, stacked is an insulating layer 53 having an opening provided such that the device electrode 52 is exposed on an electrode forming surface. The surface of the device electrode 52 is covered with the metallic layer (Ni/Au plating layer) 55. The rugged shape on the surface of the metallic layer 55 is the same as that described in the first embodiment.

The wiring layer 14a and the wiring layer 14b are electrically connected by the via conductor 15a; the wiring layer 14b and the wiring layer 14c are electrically connected by the via conductor 15b; and the wiring layer 14c and the wiring layer 14d are electrically connected by the via conductor 15c.

An under-fill material 12′ is filled in a gap between the semiconductor device 50 and the device mounting board 10. That is, the semiconductor device 50 is mounted on the device mounting board 10 through the medium of the under-fill material 12 which is an insulating resin layer disposed in contact with the rugged shape of the metallic layer 55.

(Method for Manufacturing a Semiconductor Device and a Semiconductor Module)

A method for manufacturing a semiconductor device and a semiconductor module according to the second embodiment is now described.

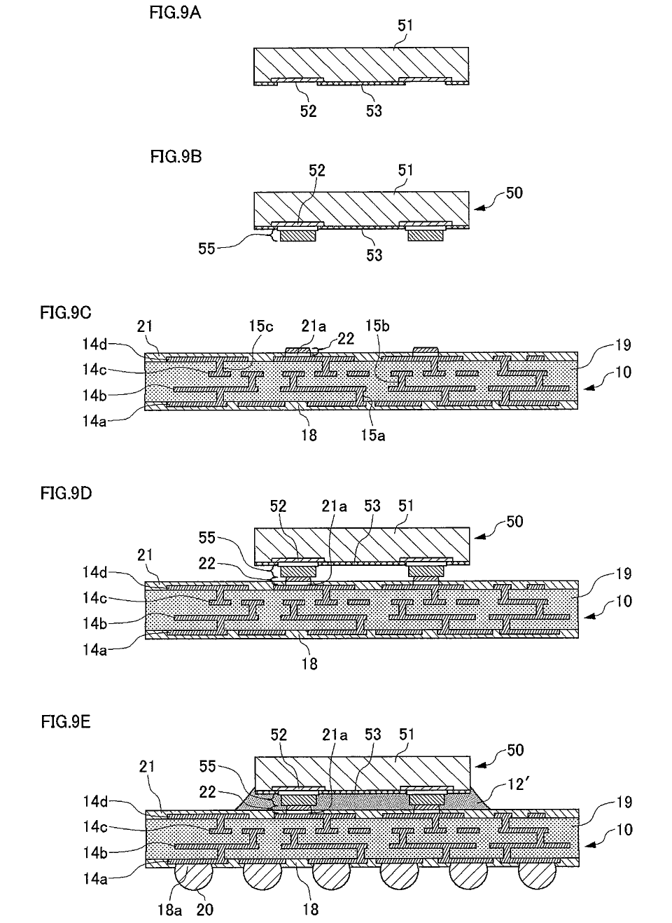

FIGS. 9A to 9E are cross-sectional views showing a process in a method for forming a semiconductor module according to the second embodiment.

As illustrated in FIG. 9A, a semiconductor substrate 51 is first prepared. A device electrode 52 is provided on the electrode forming surface of the semiconductor substrate 51. The semiconductor substrate 51 is an Si substrate, for example, on which an integrated circuit (IC) or a large-scale integrated circuit (LSI) is formed. The device electrode 52 can be formed by patterning Al, for instance. An insulating layer 53 having an opening provided such that the device electrode 52 is exposed is stacked on the electrode forming surface of the semiconductor device 50. A SiN film, polyimide film or the like is preferable as the insulating layer 53.

Then, as shown in FIG. 9B, a metallic layer 55 comprised of a Ni/Au plating layer is formed on the device electrode 52 by electroless plating.

Here, plasma processing is performed on the surface of the metallic layer 55 so that the surface of the metallic layer 55 is a rugged shape. More precisely, for example, the plasma using Ar (argon) gas is applied for 10 minutes. As a result, the rugged shape of about 2.5 nm is formed on the surface of the device electrode 52, namely the metallic layer 55. Thus, the semiconductor device 50 is manufactured through processes as described above.

Then, as shown in FIG. 9C, a device mounting board is prepared. The device mounting board 10 has a multilayered structure described with reference to FIG. 8 and is fabricated by a known buildup process or the like. The metallic layer 22 comprised of a Ni/Au plating layer is formed on a predetermined region of the wiring layer 14d.

Then, as shown in FIG. 9D, while the semiconductor device 50 is being positioned by placing it on the device mounting substrate 10 using a flip-chip bonder or the like in such a manner that the metallic layer 55 of the semiconductor device 50 is in contact with the metallic layer 22 of the device mounting substrate 10, heat and pressure are applied using a bonder apparatus at 200° C. and 10 kgf, for instance, respectively, so as to flip-chip connect the semiconductor device 50. As a result, Au—Au bonding is formed between the metallic layer 55 provided on the device electrode 52 of the semiconductor device 50 and the metallic layer 22 provided on the device mounting board 10. Moreover, the provision of a rugged shape on the surface of the metallic layer 55 assures the connection between the metallic layer 55 and the metallic layer 22 in a region where the metallic layer 55 and the metallic layer 22 are electrically connected.

Then, as shown in FIG. 9E, the under-fill material 12′ such as epoxy resin is injected into the gap between the semiconductor device 50 and the device mounting board 10. At this time, the provision of a rugged shape on the surface of the metallic layer 55 causes the under-fill material 12′ to enter the asperities thereof in a region being in contact with the under-fill material 12′, thereby improving the adhesion between the metallic layer 55 and the under-fill 12′. Openings 18a are formed in predetermined regions (mounting regions of solder balls) of the protective layer 18 by using the photolithography method, and the solder balls 20 are mounted in these openings 18a by using a screen printing method.

By employing the second embodiment as described above, the connection reliability between the device electrode 52 in the semiconductor device 50 side and the wiring layer 14d in the device mounting board 10 side is improved in the semiconductor module 30 where the semiconductor device 50 is flip-chip connected. Hence, the reliability of the semiconductor module 30 is improved. Also, the manufacturing yield of the semiconductor modules 30 can be improved and therefore the manufacturing cost of the semiconductor module 30 can be reduced.

As a modification to the present embodiments, the semiconductor device 50 may be sealed by a molded resin layer. The structure according to this modification protects the semiconductor device 50 against external influences. As a result, the reliability of the semiconductor device 50 can be further enhanced. In the present embodiments, plasma processing is performed on the surface of the metallic layer 55 formed on the device electrode 52 in the semiconductor device 50 side so as to form a rugged shape thereon. Hence a structure is achieved such that the thus formed rugged shape (asperities) is in contact with the under-fill material 12′. As a modification to this structure and method, a structure may be such that a rugged shape is formed by performing the plasma processing on the surface of the metallic layer 22 in the device mounting board 10 side and the rugged shape (asperities) is in contact with the under-fill 12′. In this modification, at least part of the metallic layer 22 is formed in such a manner as not to overlap with the metallic layer 55.

### Third Embodiment

Next, a description will be given of a mobile apparatus (portable device) provided with a semiconductor module according to the above described embodiments. The mobile apparatus presented as an example herein is a mobile phone, but it may be any electronic apparatus, such as a personal digital assistant (PDA), a digital video cameras (DVC) or a digital still camera (DSC).

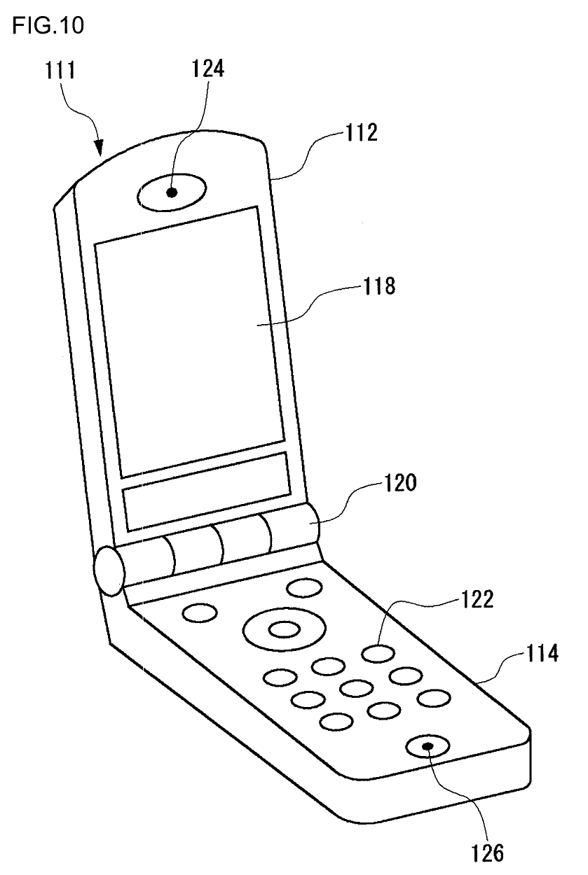

FIG. 10 illustrates a structure of a mobile phone provided with a semiconductor module 30 according to a third embodiment of the present invention. A mobile phone 111 has a structure of a first casing 112 and a second casing 114 jointed together by a movable part 120. The first casing 112 and the second casing 114 are turnable/rotatable around the movable part 120 as the axis. The first casing 112 is provided with a display unit 118 for displaying characters, images and other information and a speaker unit 124. The second casing 114 is provided with a control module 122 with operation buttons and a microphone 126. Note that the semiconductor module 30 according to each of the above embodiments of the present invention is mounted within a mobile phone 111 such as this.

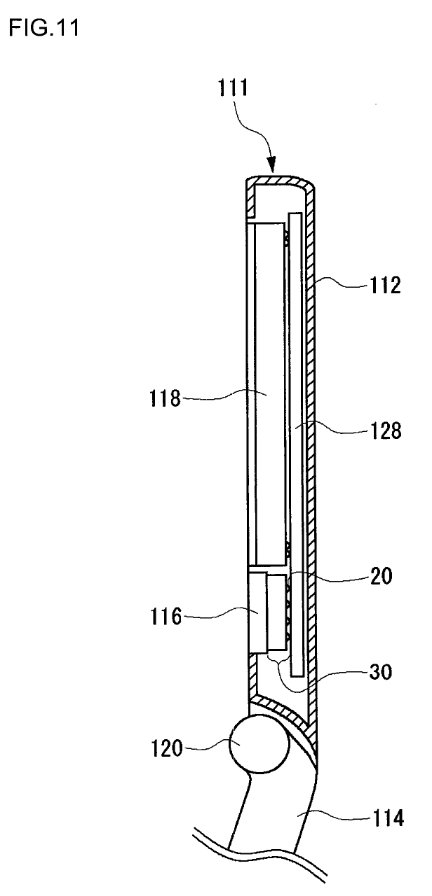

FIG. 11 is a partially schematic cross-sectional view (cross-sectional view of a first casing 112) of the mobile phone shown in FIG. 10. The semiconductor module 30 according to the third embodiment of the present invention is mounted on a printed circuit board 128 via the solder balls 20 and is coupled electrically to the display unit 118 and the like by way of the printed circuit board 128. Also, a radiating substrate 116, which may be a metallic substrate or the like, is provided on the back side of the semiconductor module 30 (opposite side of solder balls 20), so that the heat generated from the semiconductor module 30, for example, can be efficiently released outside the first casing 112 without getting trapped therein.

By employing the semiconductor module 30 according to the third embodiment of the present invention, the reliability of mounting the semiconductor module 30 on a printed wiring board improves. Thus, the reliability as to a portable device provided with such a semiconductor module 30 improves.

The present invention is not limited to the above-described embodiments only, and it is understood by those skilled in the art that various modifications such as changes in design may be made based on their knowledge and the embodiments added with such modifications are also within the scope of the present invention.

For example, in the above-described embodiment, the wiring layer of the device mounting board has a single layer but this should not be considered as limiting and it may be multilayered.

In the above-described embodiment, the bump electrode 16 of the device mounting board 10 and the device electrode 52 of the semiconductor device 50 are electrically connected to each other through the Au—Au bonding but they may be electrically connected to each other through Au—Sn (gold-tin) boding instead.

The structure according to the above-described embodiments is applicable to a process for fabricating semiconductor packages, which is called a wafer-level CSP (Chip Size Package) process. By employing such a technique, the semiconductor module can be made thinner and smaller.

While the preferred embodiments of the present invention and their modifications have been described using specific terms, such description is for illustrative purposes only, and it is to be understood that changes and variations may further be made without departing from the spirit or scope of the appended claims.

What is claimed is:

1. A semiconductor module, comprising:
a semiconductor device formed on a semiconductor substrate; and
a device mounting board which mounts said semiconductor device thereon via an insulating layer,
wherein a device electrode in said semiconductor device is formed by a plurality of metallic layers,
among the plurality of metallic layers, the depth of surface roughness of a metallic layer disposed farthest from the semiconductor substrate is larger than that of the other metallic layers thereamong, and
the insulating layer is in contact with a rugged shape of the device electrode.

2. A semiconductor module according to claim 1, said device mounting board including:
the insulating layer;
a wiring layer provided on one main surface of the insulating layer; and
a bump electrode which is electrically connected to the wiring layer and protruded from the wiring layer in an opposite side of the insulating layer,
wherein the bump electrode and the device electrode of said semiconductor device are electrically connected to each other, and
the insulating layer is in contact with the rugged shape of the device electrode.

3. A semiconductor module according to claim 1, wherein the device electrode includes a Ni/Au layer.

4. A semiconductor module according to claim 2, wherein the device electrode includes a Ni/Au layer.

5. A semiconductor module according to claim 2, wherein the wiring layer and the bump electrode are formed integrally with each other.

6. A semiconductor module according to claim 3, wherein the wiring layer and the bump electrode are formed integrally with each other.

7. A semiconductor module according to claim 4, wherein the wiring layer and the bump electrode are formed integrally with each other.

8. A semiconductor module according to claim 2, wherein a Ni/Au layer is provided on a top surface of the bump electrode.

9. A semiconductor module according to claim 3, wherein a Ni/Au layer is provided on a top surface of the bump electrode.

10. A semiconductor module according to claim 4, wherein a Ni/Au layer is provided on a top surface of the bump electrode.

11. A method for manufacturing a semiconductor module, the method comprising:
preparing a semiconductor device wherein a device electrode formed on a semiconductor substrate is formed by a plurality of metallic layers and, among the plurality of metallic layers, the depth of roughness of surface of a metallic layer disposed farthest from the semiconductor substrate is larger than that of the other metallic layers thereamong;
preparing a metallic sheet where a plurality of bump electrodes are provided in a protruding manner;
placing the metallic sheet on one main surface of an insulating resin layer in such a manner that the bump electrodes face the insulating resin layer, and exposing the bump electrodes from the other main surface of the insulating resin layer by having the bump electrodes penetrating the insulating resin layer;
placing the semiconductor device, provided with the device electrodes, on the other main surface of the insulating resin layer, and electrically connecting the bump electrodes to the device electrodes corresponding thereto; and
forming a wiring layer by selectively removing the metallic sheet.

12. A method for manufacturing a semiconductor module, the method comprising:
preparing a semiconductor device wherein a device electrode formed on a semiconductor substrate is formed by a plurality of metallic layers and, among the plurality of metallic layers, the depth of roughness of surface of a metallic layer disposed farthest from the semiconductor substrate is larger than that of the other metallic layers thereamong;
preparing a device mounting board having an electrode formed on one main face thereof;
electrically connecting the device electrode to the electrode; and
forming an insulating resin layer in between the semiconductor device and the device mounting board.
